(19) United States
(12) Patent Application Publication
(10) Pub. No.: US 2012/0006577 A1
(43) Pub. Date: Jan. 12, 2012

(54) Device For Securing Household Systems From Young Children

(75) Inventors: Kevin Brantley, Gilbert, AZ (US); Derek Underhill, Tempe, AZ (US)

(73) Assignee: Kevin Brantley, Gilbert, AZ (US)

(21) Appl. No.: 13/237,801

(22) Filed: Sep. 20, 2011

Related U.S. Application Data
(63) Continuation-in-part of application No. 12/534,125, filed on Aug. 1, 2009.

(51) Int. Cl. H01R 13/46; H05K 5/03

(52) U.S. Cl. 174/67

(57) ABSTRACT

A device for securing indoor electrical outlets, light switches, telephone jacks, computer network outlets, etc., from the reach of a young child is provided. The device can be easily installed over any standard outlet or switch. The device comprises a two-piece structure: the first piece includes a plate and a first hinge portion, and the second piece includes a cover and a second hinge portion. The plate is adapted to substantially cover the outlet or switch but still leave access to it when the cover is open, and the cover is adapted to substantially cover the first plate such that the outlet or switch is no longer accessible when the cover is closed. The plate is hingeably attached to the cover. The hinge comprises a first hinge portion integrally part of the plate and a second hinge portion integrally part of the cover. The device further includes a child-resistant lock.

### CROSS REFERENCE TO RELATED APPLICATIONS

This application is a continuation-in-part of U.S. patent application Ser. No. 12/534,125, filed Aug. 1, 2009, entitled “Device For Securing Household Systems From Young Children”, still pending.

### FIELD OF THE INVENTION

The present invention relates to a device for securing indoor electrical outlets, light switches, telephone jacks, computer network outlets, etc., from the reach of young children.

### BACKGROUND

Indoor electrical outlets are potentially dangerous attractions for young children. They are ordinarily easily reachable by toddlers and can be quite dangerous. Each year some children die of electrocution while “playing” with indoor electrical outlets.

To address this problem, many parents fit their indoor electric outlets with plastic outlet protectors. However, many children are able to remove outlet protectors. In one study, it was found that 47 percent of 4-year-olds and 31 percent of 2-year-olds were able to remove outlet protectors with a round, flat face and two prongs.

Various other devices have been developed to address the problem. However, these devices tend to be bulky, cumbersome, or expensive to manufacture.

Likewise, young children are attracted to light switches, cable TV jacks, data jacks, and coaxial data jacks, etc. While not as potentially dangerous as indoor electrical outlets, playing with these can be a nuisance and require frequent parental intervention.

Accordingly, there is a need for an improved device for securing household systems from young children.

### SUMMARY OF THE INVENTION

A device for securing indoor electrical outlets, light switches, telephone jacks, computer network outlets, etc., from the reach of a young child is provided. The device can be easily installed over any standard outlet or switch. The device comprises a two-piece structure: the first piece includes a plate and a first hinge portion, and the second piece includes a cover and a second hinge portion. The plate is adapted to substantially cover an outlet or switch but still leave access to it when the cover is open, and the cover is adapted to substantially cover the first plate such that the outlet or switch is no longer accessible when the cover is closed. The plate is hingeably attached to the cover. The hinge comprises a first hinge portion integrally part of the plate and a second hinge portion integrally part of the cover. The device further includes a child-resistant lock.

Preferably, the device has a sleek design and protrudes no more than necessary (e.g., in the case of an indoor electrical outlet, no more than about three-fourth inch in thickness). Thus, the device will not only secure the outlet but also camouflage it from an inquisitive child looking for objects in the room to play with.

Preferably, the device is made from plastic, such as polypropylene or polyethylene. Preferably, the device is manufactured using an injection molding process in two pieces. Preferably, the lock is child-resistant snap lock.

These and other aspects, features, and advantages of the present invention will become apparent from the following detailed description of preferred embodiments, which is to be read in connection with the accompanying drawings.

### BRIEF DESCRIPTION OF THE DRAWINGS

FIG. 1 shows an exemplary device for securing an indoor electrical outlet;

FIG. 2 shows the exemplary device for securing an indoor electrical outlet in an open position;

FIG. 3 shows the exemplary device for securing an indoor electrical outlet in an open position being accessible to electrical sockets;

FIG. 4 shows the exemplary device for securing an indoor electrical outlet separated into component pieces;

FIG. 5 shows the exemplary device for securing an indoor electrical outlet in a closed position; and

FIG. 6 shows a close-up perspective of an exemplary living hinge for the device according to another embodiment.

### DETAILED DESCRIPTION

While the accompanying drawings show particular preferred embodiments of the present invention, it is to be appreciated that they are meant to be illustrative, not limiting. Although the drawings and accompanying description disclose a device useable to secure an indoor electrical outlet, it is to be appreciated that other preferred embodiments of the present invention relate to devices used to cover other types of indoor outlets or switches attractive to young children, such as light switches, telephone jacks, cable TV jacks, computer networks outlets, etc. Furthermore, it is to be understood that although indoor electrical outlets having two electrical sockets are shown throughout, it is to be understood that the present invention can also be utilized for indoor electrical outlets having more, or fewer, sockets, or where the sockets are arranged differently. Furthermore, although certain types of plastics have been described as being suitable to mold the device, other types of plastic (or other suitable materials) could also be used. Additionally, it is to be understood that various other types of child-resistant locks besides the “snap lock” type described herein may be used. For example, instead of, or in addition to, a snap lock, a lock requiring a key may be used. Furthermore, it is to be understood that the term “child-resistant lock” used herein refers to a locking mechanism that require greater strength, dexterity, knowledge, ingenuity, and/or ability to open than most young children (i.e., children aged four or younger) possess.

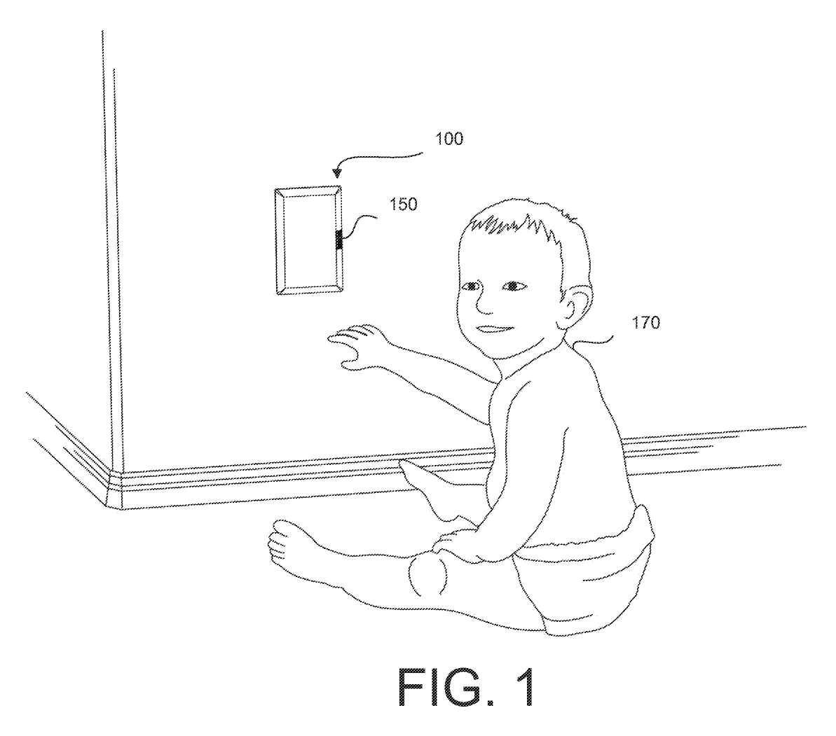

As depicted in FIG. 1, an exemplary device for securing an indoor electrical outlet 100 is shown installed over an indoor electrical outlet. As will be described in greater detail, the device 100 prevents access by a young child to an indoor electrical outlet by completely covering the indoor electrical outlet. Thus, the child, such as a baby 170, is prevented from electrical injury that could have resulted from insertion of a finger or placement of an object into the indoor electrical outlet. The device 100 includes a child-resistant lock 150 so that young children are unable to open it. The device 100 has a low profile such that it protrudes no more than about three-fourth of an inch from the wall making it is less attractive to an inquisitive child. In an embodiment, the device is about 0.679 inches (1.724 cm) in thickness, 3.258 inches (8.275 cm) in width, and (4.975 inches) (12.638 cm) in height.

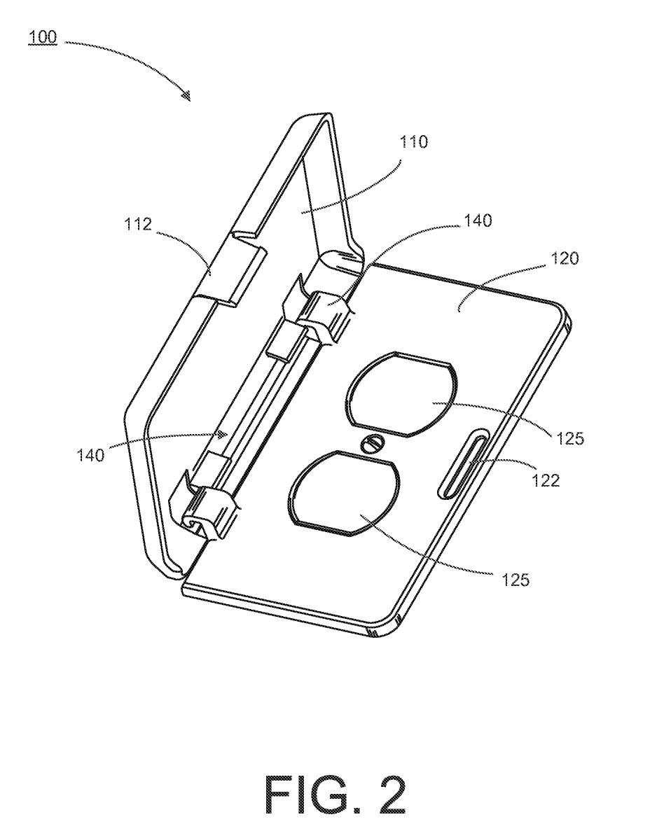

FIG. 2 shows the device for securing an indoor electrical outlet 100 in more detail. As illustrated, in perspective view, the device 100 includes a plate 120, a cover 110, and a hinge 140. The plate 120 can be sized to fit over any standard indoor electrical outlet (e.g., an electrical socket including at least one National Electrical Manufacturers Association (NEMA) 1-15 (two-pronged) socket or 5-15 (three-pronged) socket) but may be custom-sized to fit a non-standard outlet, if desired. The plate 120 is substantially planar, and can be screwed into, or otherwise attached to, an indoor electrical outlet in the same manner as a conventional indoor electrical outlet plate. The cover 110 is sized to fit over the plate 120, to enclose the plate. The hinge 140, situated as shown, allows the cover 110 to swing, thus assuming an open position or a closed position.

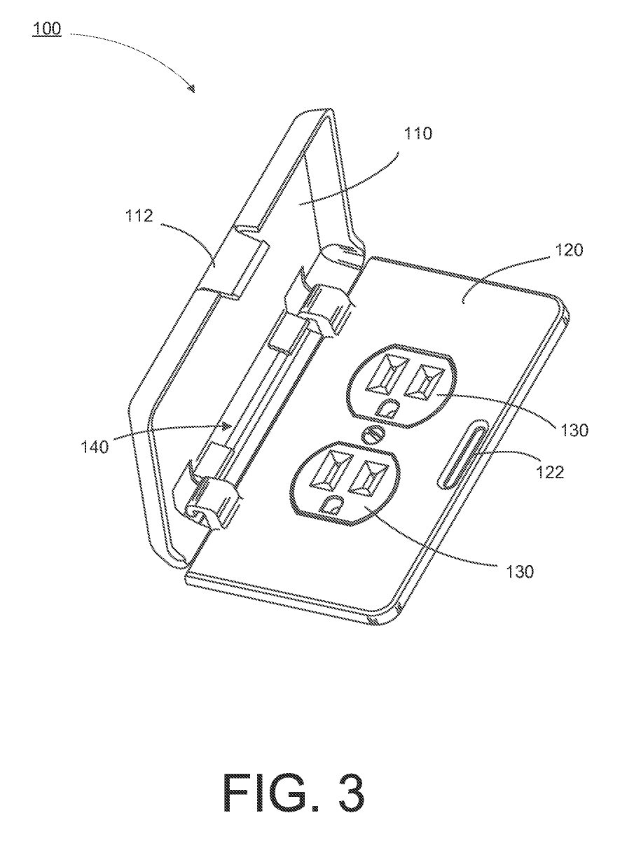

As illustrated, the device 100 is in an open position. In the open position, the child-resistant lock 150 is separated into its constituent parts: a female element 122 and a male element 112, as shown (though these could be reversed). That is, the male element 122 and the female element 112 are not inter-locked when in the open position. When the device 100 is open, the indoor electrical outlet is operationally accessible. The plate 120 includes socket holes 125 for each electrical socket of the indoor electrical outlet, as shown. Referring to FIG. 3, the socket holes 125 allow access to electrical sockets 130 (which in the illustrated case are NEMA 5-15 sockets but which may be NEMA 1-15 sockets or other types). Thus, an electrical appliance can be plugged into the outlet when the device 100 is in the open position.

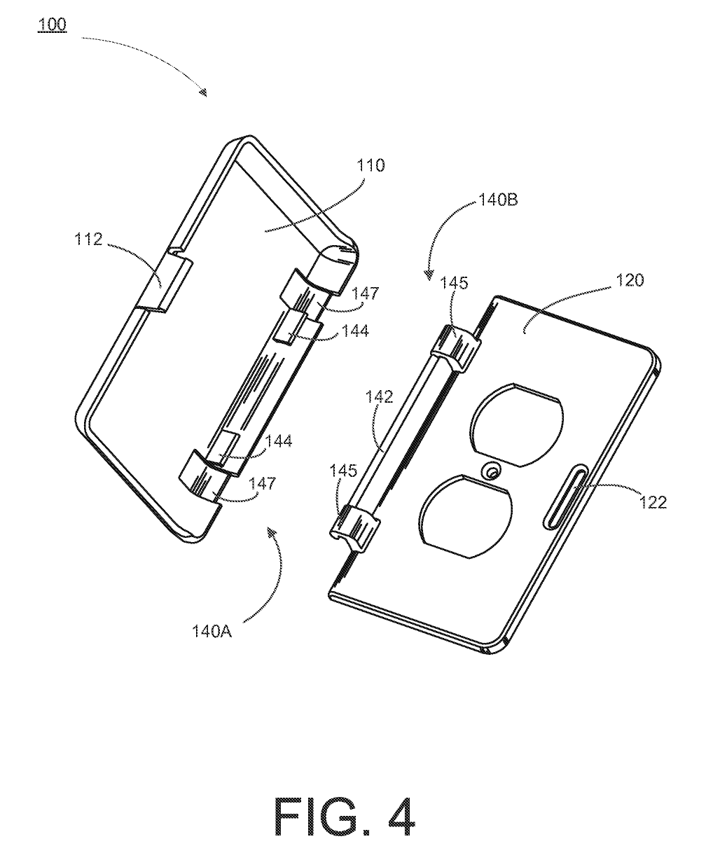

FIG. 4 shows the device for securing an indoor electrical outlet 100 separated into its two component parts. As illustrated, the cover 110 includes integral thereto a first hinge portion 140A and the plate 120 includes integral thereto a second hinge portion 140B. The first hinge portion 140A includes a set of protrusions 144 and recesses 147. The second hinge portion 140B includes a rod 142 disposed between a pair of supports 145. When the device for securing an indoor electrical outlet 100 is assembled, the first hinge portion 140A and the second hinge portion 140B are coupled forming the hinge 140, wherein the rod 142 frictionally fits under the set of protrusions 144 and effectively becomes the axis of rotation of the hinge 140.

The device 100 is made in only two pieces (i.e., the cover 110 and, integral thereto, a first hinge portion 140A, forming the first piece, and the plate 120 and, integral thereto, a second hinge portion 140B, forming the second piece). The device 100 can be made of a plastic such as, for example, polyethylene or polypropylene manufactured using an injection molding process. However, other materials and/or manufacturing methods may be used. Furthermore, to match the household decor, in this embodiment, the device 100 can be painted (either after purchase by the consumer or by the manufacturer) or the plastic used can include a colorant.

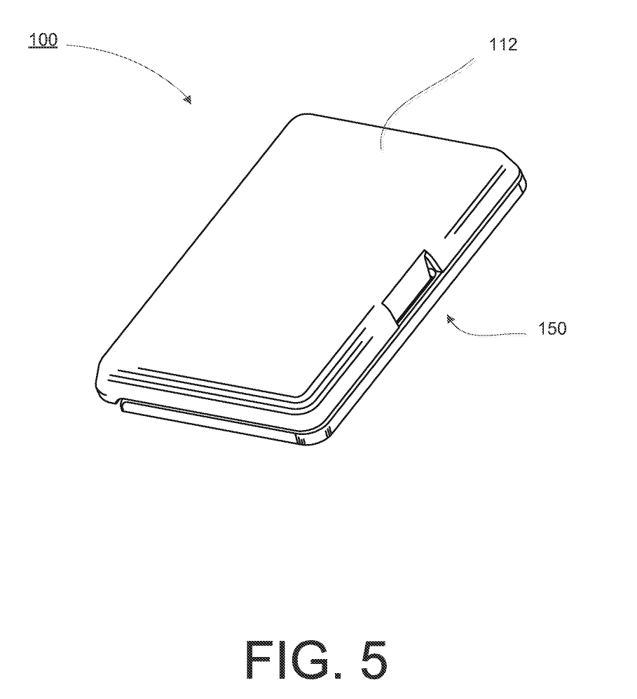

FIG. 5 shows the device for securing an indoor electrical outlet 100 in a closed position. Preferably, when the cover 110 is closed, the supports 145 are disposed within the recesses 147 and there is substantially no visible gap between the cover 110 and the plate 120. In this closed position, the child-resistant lock 150 is locked by way of the male element 112 being inserted into the female element 122, forming a friction fit, as shown. In the closed position, the cover 110 encloses the plate 120 making the electrical sockets 130 inaccessible. Because the child-resistant lock 150 cannot be opened by a young child, the indoor electrical outlet is secured and the child can safely play in the room without any danger of an electrical injury.

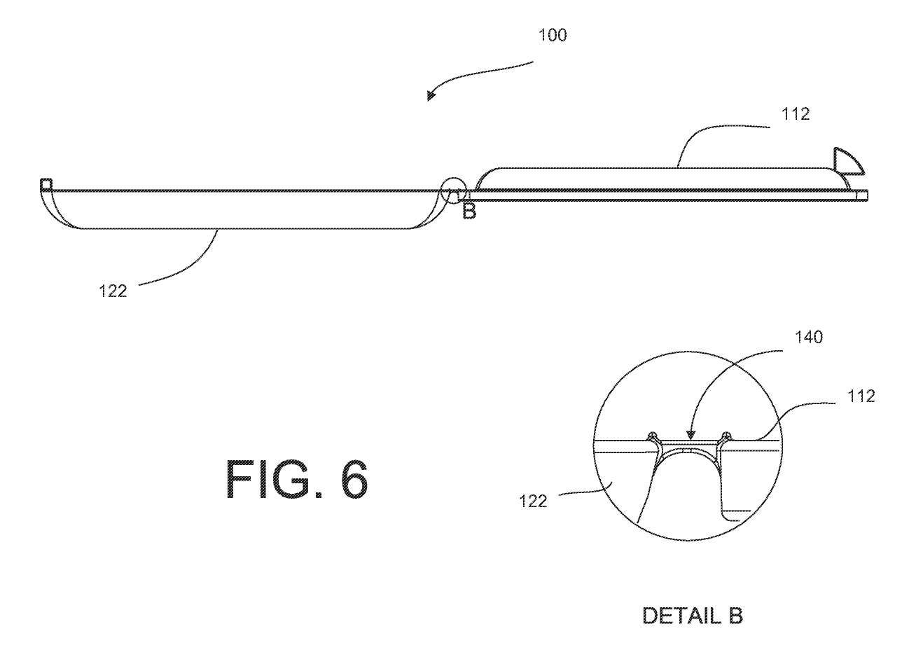

Although a particular type of hinge mechanism has thus far been illustrated, it is to be understood that various different types of hinges may be used without departing from the spirit and scope of the invention. In general, the hinge used may include moving components or a flexible material. FIG. 6 shows a close-up perspective of an exemplary hinge 140 useable for the device, according to another embodiment, described in greater detail in U.S. patent application Ser. No. 12/534,125, filed Aug. 1, 2009, entitled “Device For Securing Household Systems From Young Children”, which is incorporated herein in its entirety. As depicted, particularly in Detail B, the hinge 140 is a “living hinge”. A living hinge is formed as a thin section of plastic that connects two segments of a part to keep them together and allow the part to be opened and closed. Preferably, the hinge 140 is, on average, thinner than the rest of the device 100. Preferably, to orient the fibers for increased life, when the hinge 140 comes out of the mold and still relatively hot, the hinge 140 is plastically deformed (coined) and flexed several times.

While this invention has been described in conjunction with the various exemplary embodiments outlined above, it is evident that many alternatives, modifications and variations will be apparent to those skilled in the art. Accordingly, the exemplary embodiments of the invention, as set forth above, are intended to be illustrative, not limiting. Various changes may be made without departing from the spirit and scope of the invention.

What is claimed is:

1. A device for securing an indoor outlet, comprising:
a plate adapted to substantially cover the indoor outlet but leaving access to at least one electrical socket;
a cover adapted to enclose the plate such that the at least one electrical socket is no longer accessible when the cover is shut; and
a hinge, between the plate and the cover;
wherein the device is
assembled entirely from a first piece and a second piece, and
has a thickness of no more than three-fourth of an inch.

2. The device of claim 1, wherein the hinge includes only a first hinge portion and a second hinge portion.

3. The device of claim 2, wherein the first hinge portion is integral with the plate and the second hinge portion is integral with the cover.

4. The device of claim 3, wherein the first piece includes the first hinge portion and the plate and the second piece includes the second hinge portion and the second hinge portion and the cover.

5. The device of claim 1, wherein the device is substantially entirely plastic.

6. The device of claim 5, wherein the device is manufactured using an injection molding process.

7. The device of claim 5, wherein the plastic is polypropylene.

8. The device of claim 5, wherein the plastic is polyethylene.

9. The device of claim 1, further including a lock, the lock structured and arranged to secure the cover when the cover is shut.

10. The device of claim 9, wherein the lock is child-resistant.

11. The device of claim 10, wherein the lock is a snap lock.

12. The device of claim 11, wherein the snap lock includes inter-lockable parts.

13. The device of claim 1, wherein, the lock includes a first lock portion and a second lock portion, the first lock portion part of the first piece and the second lock portion part of the second piece.

14. The device of claim 1, wherein the indoor outlet is an indoor electrical outlet including at least one NEMA 1-15 or NEMA 5-15 electrical socket.

15. The device of claim 1, wherein the plate is adapted to leave access to at least one NEMA 1-15 or NEMA 5-15 electrical socket.

16. The device of claim 1, wherein the outlet is a telephone jack.

17. The device of claim 1, wherein the outlet is a network jack.

18. A device for securing an electrical switch, comprising:
a single assembled piece, including
a first portion adapted to substantially cover the electrical switch leaving access to the electrical switch;
a second portion adapted to enclose the first portion such that the electrical switch is no longer accessible when the second portion is in a closed position; and
a third portion, between the first portion and the second portion, including a hinge.

19. A device for securing an indoor electrical outlet, comprising:
a first portion adapted to substantially cover the indoor electrical outlet leaving access to one or more electrical socket;
a second portion adapted to enclose the first portion such that the one or more electrical sockets is no longer accessible when the second part is in a closed position; and
a third portion, between the first portion and the second portion, the third portion forming a living hinge.

20. The device of claim 19, wherein the one or more electrical socket is a NEMA 1-15 electrical socket or a NEMA 5-15 electrical socket.
